(19) United States
(12) Patent Application Publication
(10) Pub. No.: US 2010/0192841 A1
(43) Pub. Date: Aug. 5, 2010

(54) REINFORCING METHOD OF SILICA GLASS SUBSTANCE AND REINFORCED SILICA GLASS CRUCIBLE

(75) Inventors: Toshio TSUJIMOTO, Akita-shi (JP); Hiroya Ishizuka, Akita-shi (JP); Naotaka Fumoto, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: JAPAN SUPER QUARTZ CORPORATION, Tokyo (JP)

(21) Appl. No.: 12/759,324

(22) Filed: Apr. 13, 2010

Related U.S. Application Data
(63) Continuation of application No. 11/864,239, filed on Sep. 28, 2007.
Application No. 11/864,239 is a division of application No. 10/673,180, filed on Sep. 30, 2003.

(30) Foreign Application Priority Data
Oct. 9, 2002 (JP) 2002-295832

(51) Int. Cl. C30B 15/10

(52) U.S. Cl. 117/208

(57) ABSTRACT

A process reinforcing a silica glass substance, such as a silica glass crucible, is provided without intermixing an impurity. The process comprises forming a silica glass powder layer on a surface of the silica glass substance, and crystallizing said silica glass powder layer under high temperature. As for a silica glass crucible, the process for reinforcing the silica glass crucible and the reinforced silica glass crucible are provided, wherein the silica glass powder layer on the whole or a part of the surface of the crucible is formed and then, crystallized under a temperature at the melting of a silicon raw material being charged into said quartz glass crucible.

### BACKGROUND OF THE INVENTION

1. Field of the Invention

The present invention relates to a reinforcing process of a silica glass substance, especially to a process reinforcing a silica glass crucible used for pulling a silicon single crystal for a semiconductor, and a reinforced silica glass crucible.

2. Discussion of the Background

The silica glass substance used for a semiconductor jig and the silica glass crucible used for pulling the silicon single crystal are used under high temperature of more than 1000 degree C. When the temperature becomes over 1200 degree C., the viscosity of the silica glass is decreased, and the deformation is a problem. In the case of the silica glass crucible, since the crucible is used under the temperature of more than a melting point of silicon, i.e., 1410 degree C., the crucible is used by being held in a carbon susceptor, in order to keep the form of the crucible. Recently, the large size silica crucible having the diameter of more than 28 inches, i.e., 700 mm, has been used in accordance with increasing a diameter of a silicon wafer, and the pulling time becomes long with increasing the charging amount of a silicon metal in the crucible, so that the crucible becomes to receive a higher thermal load. As the result, there is a problem that the crucible is deformed, that is, for example, a side wall of the crucible is fallen down to the inside in the carbon susceptor, or the crucible is sagged by own weight. When the crucible is deformed greatly during the pulling of the silicon single crystal, the pulling must be stopped, so that the big cost loss is occurred.

As for the prior art of such process reinforcing the silica glass substance, the process has been known, in which said substance is reinforced by doping an impurity to the silica glass to increase the viscosity of the glass or by crystallizing the silica glass with a crystallization promoter, such as barium etc., (Japanese Patent Laid Open No. Hei 8-2932 and No. Hei 9-110590). However, in these processes, since the impurity is used, there is a problem in the semiconductor field, where the use of the impurity is disliked extremely. On the other hand, it has been proposed that the technology, in which a quartz crystalline particle is embedded in the surface of the silica glass crucible, and the adhered particle is used as a nucleus to crystallize the silica glass at the time of melting the poly-crystalline silicon under the high temperature (Japanese Patent Laid Open No. 2000-169283), instead of the method using the impurity. As for this technology, although it is possible to avoid the contaminant of the impurity by using the quartz particle, there is a problem that since an amorphous phase exists between the quartz crystal particles, a part of the crystal layer becomes to be released easily by the difference of thermal expansion coefficients in accordance with progressing the around crystallization. Furthermore, the crystal layer becomes un-uniform easily.

### SUMMARY OF THE INVENTION

The present invention solves the conventional above-described problems, and has an object to provide a technology, in which the surface of the quartz glass substance is crystallized effectively and uniformly to be reinforced without inducing the impurity into the silica glass substance or the silica glass crucible.

In the present invention, as for the silica glass substance or the silica glass crucible, the following reinforcing technologies are provided.

[1] A process reinforcing a silica glass substance, the process comprising;

forming a silica glass powder layer on a surface of the silica glass substance, and

crystallizing the silica glass powder layer under a high temperature to reinforce the silica glass substance

[2] The process according to [1], wherein the silica glass substance is a silica glass crucible, and the crucible is reinforced by

forming the silica glass powder layer on the whole or a part of a surface of a silica glass crucible, and

crystallizing the silica glass powder layer on the surface of the crucible under a high temperature at the time of melting a silicon metal which is charged into the quartz glass crucible.

[3] The reinforcing method according to above [1] or [2], wherein the silica glass powder layer formed on the surface of the quartz glass substance or the quartz glass crucible becomes a porous layer of the silica glass powder by being sintered under a lower temperature than the crystallization temperature.

[4] The reinforcing method according to above [1], [2], or [3], wherein the silica glass powder layer is formed by

making the silica glass powder into a slurry containing a binder,

coating said slurry on the surface of the silica glass substance or the surface of the quartz glass crucible, and

solidifying the coated slurry.

[5] The reinforcing method according to any one of from above [1] to [4],

wherein the silica glass powder layer consists of the fine and coarse silica particles, wherein more than 20 weight % of all powder are the fine silica particles having smaller particle size than 10 μm, and remaining powder are the coarse silica particles having less than 150 μm.

[6] A quartz glass crucible,

wherein the silica glass powder layer is formed on the whole or a part of the surface of the crucible.

[7] The silica glass crucible according to above [6],

wherein the silica glass powder layer is formed on the whole or in the ring configuration on the outside surface of the crucible, or on the whole of the inside surface or in the ring configuration on a part of the inside surface being not contacted with a melted silicon.

[8] The silica glass crucible according to above [6] or [7],

wherein the silica glass powder layer is formed on the whole or a part of the surface of the crucible and the silica glass powder layer consists of the fine and coarse silica particles, wherein more than 20 weight % of all powder are the fine silica particles having smaller particle size than 10 μm, and remaining powder are the coarse silica particles having less than 150 μm.

[9] A method for pulling a silicon single crystal, the method comprising;

using the silica glass crucible having the silica glass powder layer on the whole or a part of the surface of the crucible, and

reinforcing the silica glass crucible by crystallizing the silica glass powder on the surface of the crucible under a high temperature at the time of melting the silicon which is charged into the crucible.

### DETAILED DESCRIPTION OF THE PREFERRED EMBODIMENTS

The process of the present invention is forming the silica glass powder layer on the surface of the silica glass substance, and reinforcing the silica glass substance by crystallizing the said silica glass powder layer under the high temperature. As for the method being applied to the silica glass crucible, the present invention is the method for reinforcing the quartz glass crucible, forming the silica glass powder layer on the whole or a part of the surface of the silica glass crucible, and baking and crystallizing the silica glass powder on the surface of the crucible under the high temperature at the pulling process.

In the present invention, the silica glass powder is used as a material promoting the crystallization on the surface of the quartz glass crucible. When the quartz glass is made into the fine powder, the surface energy of the powder becomes high, and it is easy to crystallize rather than a bulky silica glass. When the temperature is raised to about 1000 degree C., the silica glass powder layer begins to sinter to form a porous glass layer and a firmly adhering layer is deposited on the surface of the silica glass. Furthermore, when the temperature is raised to about 1300 degree C., since the crystallization is progressed from the surface of the porous layer, the crystallization speed of the porous layer is faster than the bulky silica substance. Since said porous glass layer is crystallized, the reinforcement of the quartz glass substance is increased, so that it is possible to prevent the deformation under the high temperature. When the time for keeping the high temperature becomes long, the silica glass substance becomes to be crystallized itself, so that the reinforcement is increased further.

In addition, as described above, it has been already known that the method, in which the crystalline quartz particles are embedded in the surface of the glass crucible to be used as a nucleus to crystallize the around amorphous glass phase at the time of the heating. However, in this method, there are problems that the quartz particles is released from the surface of the crucible because the thermal expansion coefficient of the quartz is different from that of silica glass, especially the phase transition from α-quartz to β-quartz occurs at 573 degree C. arises serious problem. When the silica glass powder is used, there are no such problems, and the uniform crystal phase can be given.

As for the fine quartz glass powder layer, it is preferable that the silica glass powder layer comprises the fine and coarse silica particles, wherein more than 20 weight % of all powder are the fine silica particles having smaller particle size than 10 μm, and remaining powder are the coarse silica particles having less than 150 μm. Since the powder having the particle size of more than 150 μm is hard to be crystallized, it is not preferable. The powder having the particle size of less than 150 μm is easy to be crystallized, and more than 20 weight % of the powder having the particle size of less than 10 μm is more preferable. Moreover, it is preferable that said silica glass powder layer comprises the coarse and fine particles. The quartz glass powder is shrunk at the time of the sintering in general. However, as for the quartz glass powder layer comprising the coarse and fine particles, since the shrinkage percentage can be controlled to several %, it is possible to form the uniform crystal phase having no crack. On the other hand, when the silica glass powder layer is formed by the powder having narrow particle size distribution, that is, the almost particle has the same size even when the particle size is less than 10 μm, cracks are aroused because said silica glass powder layer is shrunk more than 10% by sintering under the high temperature, so that the strength is lower even when the layer is crystallized.

The method for forming the silica glass powder layer is not limited. For example, it is available that a slurry comprising the silica glass powder and water is coated on the surface of the silica glass substance or the silica glass crucible to be dried. In order that said silica powder layer is not released when the crucible is carried or set in a furnace of puller, it is preferable that the silica glass powder layer on the surface of the crucible is sintered under the lower temperature than the crystallization temperature to be the porous glass layer. Since the porous glass layer is baked on the surface of the crucible by sintering, the glass layer becomes hard to be released. It is preferable that the sintering temperature is from more than 1000 degree C. to less than 1300 degree C., more preferably about 1200 degree C. As for the silica glass crucible having the porous glass layer, the crystallization is progressed from said porous layer by heating under the high temperature at the pulling process of the silicon single crystal, and reinforces the crucible.

As the other method for forming the silica glass powder layer, it is also available that the binder is added to the slurry containing the silica glass powder, and said slurry is coated on the surface of the silica glass substance to be reinforced to form the silica glass powder layer. It is preferable that the binder is an organic substance, such as acrylics or vinyl acetate etc., which can be vaporized during the temperature-raising in a furnace of puller. It is possible to carry out the coating easily by adding the binder to increase a tackiness of the slurry. If the vaporization of the binder is disliked, the above-described sintering method is preferably. The silica glass powder layer formed on a silica glass crucible by these method, is sintered to be the porous layer by heating under the high temperature at the pulling process of the silicon single crystal, and the crystallization begins and progresses from said porous layer.

In addition, as the binder, it is available that the partial hydrolyzate of an alkoxysilane oligomer is used. In this case, after forming the silica glass powder layer, it is available that the solution containing the partial hydrolyzate of the alkoxysilane oligomer is sprayed on said layer and is baked at from 100 degree C. to 500 degree C. Siliceous materials formed from alkoxysilane prevent the releasing of the silica glass powder layer.

In this case, the partial hydrolyzate of an alkoxysilane oligomer used in the present invention is obtained by a process in which the alkoxysilane oligomer is hydrolyzed under the controlled reaction conditions, and after the alcohol is removed, each generated OH group is bonded together to form the silica sol. As a suitable starting material, one or more silane compounds having at least one, preferably more than two, and more preferably more than three alkoxyl groups, can be used. Concretely, tetraethoxysilane (=ethylsilicate), tetrapropoxysilane, methyltriethoxysilane, dimethylmethoxy-silane, phenyltriethoxysilane, chlorotrimethylsilane, various kinds of silane coupling reagents, such as vinyltriethoxysilane, γ-aminopropyltriethoxy-silane, etc., also can be mentioned. Ethylsilicate, which is the cheapest and to be easily hydrolyzed, is preferred.

These alkoxysilanes are used as the hydrolyzate, which is partially hydrolyzed beforehand. The partial hydrolysis is carried out in the presence of an acid catalyst, i.e., an inorganic acid, such as hydrochloric acid, or an organic acid, such as p-toluene sulfonic acid, and water. Then, the reaction conditions, including, whether using the acid catalyst or not, the amount of acid catalyst, the amount of the water for hydrolysis in the reaction system, the reaction temperature and the reaction time, are adjusted to obtain the partial hydrolyzate of alkoxysilane oligomer.

In the case of any above-described methods, the silica glass powder layer is formed preferably by that the slurry, in which more than 20 weight % of all powder comprises the silica particle having the particle size of less than 10 μm, is coated on the surface of the silica substance or the crucible in the concentration of more than 1 mg/cm² if changed into silica glass, it is suitable that the thickness of the coated silica glass powder layer is more than 0.1 mm. When the thickness is thinner than 0.1 mm, the strength is not enough to prevent the deformation of the silica substance.

When the silica glass crucible is reinforced by forming the silica glass powder layer, it is available that the silica glass powder layer is formed on the outside surface of the crucible. As for an adhesion range of the silica glass powder layer, it is available that said layer is formed on the whole or a part of the outside surface of the crucible. When the silica glass powder layer is formed on a part of the crucible, it is available that said layer is formed in the ring configuration so as to go around the periphery of the crucible or in the other configuration. In addition, when said layer is formed on the inside surface of the crucible, it is available that said layer is formed in the ring configuration around the inner circumference on an upper end portion not contacted with a molten silicon held in the crucible.

As for the conventional silica glass substance, after forming the fine quartz glass powder layer, the formed silica glass powder layer is crystallized under the high temperature to reinforce the silica glass substance. As for the conventional silica glass crucible, the silica glass powder on the surface of the crucible is crystallized by heating under the high temperature at the melting of the silicon raw material being charged into the crucible having the silica glass powder layer on the whole or a part of the surface of the crucible. In this way, the crystallization of the surface of the crucible is carried out at the melting of the silicon raw material. In the case that the surface of the crucible is crystallized before setting in the puller, the crystal is abraded by the difference of the thermal expansion coefficients between the crystal phases and the glass phases, and the phase transformation from α to β phase when the temperature is increasing.

The silica glass substance or the silica glass crucible is reinforced by the above-described crystallization of the silica glass powder and its deformation is prevented under the high temperature. According to the above-described reinforcing process, it is not necessary to use the impurity, and the impurity is not intermixed since the fine quartz glass powder is crystallized by using the property of said powder itself. So, said reinforcing process is suitable in the production of a high purity material, such as the silicon single crystal by the pulling method. More particularly, in pulling of the silicon single crystal, the high purity silicon single crystal, in which the impurity is not intermixed, can be pulled, by using the silica glass crucible having the fine quartz glass powder layer on the whole or a part of the surface of the crucible, and crystallizing the silica glass powder on the surface of the crucible under the high temperature at the time of melting the silicon raw material being charged into said crucible, to reinforced said crucible.

### EXAMPLES

Hereinafter, the present invention is further explained by way of the examples.

### Example 1

As for the piece of the silica glass, which has the width of 2 cm, the length of 9 cm, and the thickness of 1 cm, a bending test by the own weight was carried out while supporting said piece at two points. The distance between the two points was 7 cm. The temperature was 1500 degree C., and the keeping time was 10 hours, and the temperature-raising time was 2 hours. The dropped depth of the central portion was measured, and the deformation at the time of the high temperature was evaluated. These results were shown in Table 1.

TABLE 1

| | Sample 1 | Sample 2 | Sample 3 | Sample 4 | Sample 5 | Sample 6 |
|---|---|---|---|---|---|---|
| Deformation | 9 | 5 | 3 | 16 | 17 | 17 |
| Amount (mm) | | | | | | |

[Sample 1] A fine spherical silica powder being produced by FUSO CHEMICAL CO., LTD., was used as the fine quartz glass powder. As for the impurities, an alkali metal was less than 1 ppm, and a heavy metal was less than 0.1 ppm. The slurry was prepared, by mixing 4.5 g of the glass powder having the average particle size of 7 μm, 0.5 g of the glass powder having the average particle size of 1 μm, and 0.25 g of the glass powder having the average particle size of 0.3 μm, and adding an ultra pure water to the mixed powder. The prepared slurry was coated on the one side of the piece of the quartz glass with 0.5 mm of the layer thickness.

[Sample 2] The slurry was prepared by pulverizing a high purity synthetic silica powder having the average particle size of 230 μm, which was used as the raw material of the crucible, by a ball mill. First, 2.3 kg of the synthetic silica powder, 6.8 kg of high purity silica balls having the diameter of 10 mm, and 765 g of the ultra pure water were taken into a nylon pot to be pulverized for 40 hours. The obtained glass powder is the mixed powder consisting of the fine particle having the particle size of less than 10 μm of 58 weight % and the coarse particle having the particle size larger than 10 μm of 42 weight %. As for the amount of the impurities in the obtained glass powder, the alkali metals and the other heavy metals were less than 1 ppm. The prepared slurry was coated on the one side of the piece of the quartz glass with 0.5 mm of the layer thickness.

[Sample 3] The slurry was prepared by pulverizing a high purity synthetic silica powder having the average particle size of 230 μm, which was used as the raw material of the crucible, by a ball mill. First, 1 kg of the synthetic silica powder, 4.3 kg of high purity alumina balls having the diameter of 5 mm, and 333 g of the ultra pure water were taken into a high purity alumina pot to be pulverized for 30 hours. The given glass powder is the mixed powder consisting of the fine particle having the particle size of less than 10 μm of 68 weight % and the coarse particle having the particle size larger than 10 μm of 22 weight %. As for the amount of the impurities in the given glass powder, Al was 500 ppm, and the alkali metals and the other heavy metals were less than 1 ppm. The prepared slurry was coated on the one side of the piece of the quartz glass with 0.5 mm of the layer thickness.

[Sample 4] As the comparison reference, the slurry was prepared by pulverizing a crystalline natural quartz powder being used as the raw material of the crucible by the ball mill. First, 1 kg of the natural quartz powder, 4.3 kg of the high purity alumina balls having the diameter of 5 mm, and 333 g of the ultra pure water were taken into the high purity alumina pot to be pulverized for 30 hours. In the given glass powder, the fine particle having the particle size of more than 10 μm was 55 weight %. As for the amount of the impurities in the given glass powder, Al was 550 ppm, and the alkali metals and the other heavy metals were less than 3 ppm. The prepared slurry was coated on the one side of the piece of the silica glass with 0.5 mm of the layer thickness.

[Sample 5] As the comparison reference, the slurry was prepared by adding 4 g of the ultra pure water to 5.25 g of the fine spherical silica powder having the average particle size of 1 μm, which was the fine silica powder having the same particle size. The prepared slurry was coated on the one side of the piece of the silica glass with 0.5 mm of the layer thickness.

[Sample 6] As the comparison reference, the sample being not coated was tested.

As for the samples 1, 2 and 3, in which the silica glass powder was coated according to the present invention, the deformation amounts were remarkably small. After testing, it was confirmed by X-ray diffraction analysis that the coated layers of the samples 1, 2 and 3 were the crystal layers of cristobalite.

As the reason why the deformation amount of the sample 2 was smaller than said amount of the sample 1, it was considered that the crystallization was more enhanced with strain generated in the glass powder when the silica glass was pulverized.

As the reason why the deformation amount of the sample 3 was smaller than said amount of the sample 1, it was considered that the crystallization was more enhanced with aluminum being intermixed and strain generated in the glass powder when the silica glass was pulverized. As the reason why the deformation amount of the sample 3 was smaller than said amount of the sample 2, it was considered that the crystallization was more enhanced with intermixed aluminum when the silica glass was pulverized by alumina balls.

As for the sample 4, in which the crystalline quartz powder was used, there was almost no effect for reinforcing the glass substance. When the sample 4 was rubbed after testing, the coated layer was abraded easily. The reason why said layer was abraded easily was that said layer was not sintered at the time of the heating since the crystalline quartz powder was used.

As for the sample 5, in which the fine particle having the same particle diameter was used, there was also no effect. It was observed that the sample 5 after the test had a countless crack. Although, the cristobalite crystal was confirmed in the coated layer by the X-ray diffraction analysis, the reason of no effect is considered that the sample 5 was deformed since the strength was not increased by the cracks.

### Example 2

The same slurry of the silica glass powder as the sample 3 of Example 1 was coated on the outside surface of quartz glass crucible for pulling the semiconductor, and the coated slurry was heated under the temperature of 1200 degree C., in which said slurry was not crystallized, to bake the coated layer. When the layer after the baking was rubbed, said layer was not abraded, and adhered to the crucible strongly. Moreover, said crucible was washed with a hydrochloric acid. By using said crucible, the pulling test of the silicon single crystal was carried out, wherein a multi-pulling test, in which the silicon single crystal was pulled 4 times, was carried out. As the comparison reference, the same pulling test was carried out to the crucible being not formed with the above-described coated layer. Each said pulling test was carried out by using 5 crucibles. As the result, as for the comparison sample, 4 crucibles were deformed, so that said pulling test had to be stopped during the test. On the other hand, as for the crucible of the present invention, all 5 crucibles were not deformed.

According to the present invention, the silica glass substance or the silica glass crucible is reinforced by the crystallization of the silica glass powder and the deformation under the high temperature is prevented. As for the process of the present invention, since the silica glass crucible was crystallized by using the property of the silica glass powder, the impurity is not intermixed. So, said process is suitable to the production of the high purity material, such as the silicon single crystal by the pulling method.

1-15. (canceled)

16. A silica glass crucible, consisting of
a crucible main body comprising silica glass and having an inside surface and an outside surface, and
a silica glass powder layer formed on the whole or in a ring configuration on the outside surface of the crucible main body, and/or in a ring configuration on an upper end portion of the inside surface of the crucible main body, wherein
the silica glass powder layer consists of silica glass powder and binder consisting of an organic substance,
silica glass powder of the silica glass powder layer consists of fine silica particles and coarse silica particles of synthetic silica glass in a mixed state,
the fine silica glass particles constitute more than 20 weight % to 68 weight % of all the silica glass powder and have particle size smaller than 10 μm, and
the coarse silica glass particles constitute the remaining silica glass powder and have particle size from 10 μm to smaller than 150 μm, and
an area density of a silica glass in the silica glass powder layer is more than 1 mg/cm².

17. The silica glass crucible of claim 16, wherein the silica glass powder layer is formed on the whole of the outside surface of the crucible main body.

18. The silica glass crucible of claim 16, wherein the silica glass powder layer is formed in a ring configuration on the outside surface of the crucible main body, and the silica glass of the crucible main body is exposed on a bottom portion of the outside surface.

19. The silica glass crucible of claim 16, wherein the silica glass powder layer is formed in a ring configuration on the upper end portion of the outside surface of the crucible main body, and the silica glass of the crucible main body is exposed on a bottom portion of the inside surface.

20. The silica glass crucible of claim 18, wherein the silica glass powder layer is further formed in a ring configuration on the upper end portion of the inside surface of the crucible main body, and the silica glass of the crucible main body is exposed on a bottom portion of the inside surface.

21. The silica glass crucible of claim 19, wherein the silica glass powder layer is further formed in a ring configuration on the upper end portion of the inside surface of the crucible main body, and the silica glass of the crucible main body is exposed on a bottom portion of the inside surface.

22. The silica glass crucible of claim 16, wherein the silica glass powder has a particle size distribution that enables to control shrinkage percentage of the silica glass powder layer to be less than 10% at a time of sintering the powder layer.

23. The silica glass crucible of claim 16, wherein the silica glass powder layer has a thickness larger than 0.1 mm.

24. The silica glass crucible of claim 16, wherein the synthetic silica glass has an alkaline metal concentration of less than 1 ppm.

25. The silica glass crucible of claim 16, wherein the coarse silica glass particles constitute 42 weight % to less than 80 weight % of all the silica glass powder.

26. The silica glass crucible of claim 16, wherein the organic substance is at least one selected from the group consisting of acrylics and vinyl acetate.

27. The silica glass crucible of claim 16, wherein the organic substance is a partial hydrolyzate of an alkoxysilane oligomer.

28. The silica glass crucible of claim 16, wherein the synthetic silica glass has a heavy metal concentration of less than 0.1 ppm.

29. The silica glass crucible of claim 16, wherein the synthetic silica glass has a total concentration of alkali metals and heavy metals of less than 1 ppm.

30. The silica glass crucible of claim 16, wherein the fine silica particles and the coarse silica particles are produced by pulverizing the synthetic silica glass in a ball mill.
